(19) United States
(12) Patent Application Publication
(10) Pub. No.: US 2023/0317430 A1
(43) Pub. Date: Oct. 5, 2023

(54) WAFER PLACEMENT TABLE

(71) Applicant: NGK Insulators, Ltd., Nagoya-City (JP)

(72) Inventors: Ikuhisa MORIOKA, Handa-City (JP); Hiroshi TAKEBAYASHI, Handa-City (JP); Tatsuya KUNO, Nagoya-City (JP); Seiya INOUE, Handa-City (JP)

(73) Assignee: NGK Insulators, Ltd., Nagoya-City (JP)

(21) Appl. No.: 18/164,799

(22) Filed: Feb. 6, 2023

(30) Foreign Application Priority Data
Mar. 31, 2022 (JP) 2022-059152

(51) Int. Cl. H01J 37/32; H01L 21/687

(52) U.S. Cl. CPC H01J 37/32715; H01J 37/32642; H01J 37/32174; H01L 21/68757; H01L 21/68785; H01J 2237/334; H01J 2237/332

(57) ABSTRACT

The wafer placement table includes a ceramic plate and a conductive substrate. The ceramic plate includes a plate annular portion at an outer circumference of a plate central portion having a wafer placement surface. The plate annular portion has an annular focus ring placement surface. The conductive substrate is provided on a lower surface of the ceramic plate and used as a radio-frequency source electrode. At the same height from the focus ring placement surface in the plate annular portion, a focus ring attraction electrode and a focus-ring-side radio-frequency bias electrode to which a bias radio frequency is supplied are embedded.

### BACKGROUND OF THE INVENTION

### 1. Field of the Invention

The present invention relates to a wafer placement table.

### 2. Description of the Related Art

A wafer placement table is used to perform, for example, CVD or etching on wafers by utilizing plasma. For example, a wafer placement table disclosed in PTL 1 includes a ceramic substrate and a cooling substrate. The ceramic substrate includes a central portion that has a circular wafer placement surface and an outer peripheral portion that has an annular focus ring placement surface on the outer peripheral side of the central portion. A wafer placed on the wafer placement surface is electrostatically attracted to the wafer placement surface when a direct-current voltage is applied to a wafer attraction electrode embedded in the central portion of the ceramic substrate. The focus ring placed on the focus ring placement surface is electrostatically attracted to the focus ring placement surface when a direct-current voltage is applied to a focus ring attraction electrode embedded in an outer peripheral portion of the ceramic substrate. A first radio frequency power source that generates a radio frequency for a source for producing plasma and a second radio frequency power source that generates a radio frequency for a bias for pulling ions into the wafer are connected to the cooling substrate.

### CITATION LIST

### Patent Literature

PTL 1: JP 2018-206804 A

### SUMMARY OF THE INVENTION

Meanwhile, in the above-described wafer placement table, it can be thought that the wafer attraction electrode and a wafer-side bias electrode are embedded in the central portion so as to be arranged in order of proximity to the wafer placement surface, the focus ring attraction electrode and a focus-ring-side bias electrode are embedded in the outer peripheral portion so as to be arranged in order of proximity to the focus ring placement surface, and a source radio-frequency power source is connected to the cooling substrate. The wafer-side bias electrode is a radio frequency electrode for pulling ions into the wafer, and the focus-ring-side bias electrode is a radio frequency electrode for pulling ions into the focus ring. Efficiency of generation of the plasma to be generated above the wafer or above the focus ring increases as a capacitance C of a ceramic dielectric layer between the bias electrode and the placement surface (C=εS/d (C: capacitance [F], ε: permittivity [F/m], S: area of electrode [m²], d: thickness of dielectric layer [m])) increases. However, when the bias electrode is disposed below the attraction electrode, the thickness of the dielectric layer increases, and accordingly, the capacitance reduces and the efficiency of generation of plasma reduces.

The present invention is made to solve the above-described problem and is mainly aimed at an increase of the efficiency of generation of plasma without obstructing attraction of a target.

[1] A first wafer placement table according to the present invention includes a ceramic plate including a plate annular portion that includes a focus ring placement surface having an annular shape and that is disposed outside a plate central portion including a wafer placement surface having a circular shape, and a conductive substrate that is provided on a lower surface of the ceramic plate and that is used as a radio-frequency source electrode. At a same height from the focus ring placement surface in the plate annular portion, a focus ring attraction electrode and a focus-ring-side radio-frequency bias electrode to which a bias radio frequency is supplied are embedded.

In this wafer placement table, the focus-ring-side radio-frequency bias electrode is disposed at the same height as the focus ring attraction electrode instead of being disposed below the focus ring attraction electrode. Thus, the distance between the focus-ring-side radio-frequency bias electrode and the focus ring placement surface (corresponding to the above-described thickness of the dielectric layer) reduces, and the capacitance between them increases. Accordingly, efficiency of generation of plasma above the focus ring increases. Since the distance between the focus ring attraction electrode and the focus ring placement surface is small, no inconvenience is caused for the attraction of the focus ring to the focus ring placement surface. Accordingly, the efficiency of generation of plasma above the focus ring can be increased without obstructing attraction of the focus ring (a target).

Herein, “above” or “below” does not represent an absolute positional relationship. The “above” and “below” represent relative positional relationships. Accordingly, “above” and “below” may represent “below” and “above”, “left” and “right”, or “front” and “rear” depending on the orientation of the wafer placement table.

[2] In the first wafer placement table described above (the wafer placement table described in [1] above), in plan view, the focus ring attraction electrode and the focus-ring-side radio-frequency bias electrode may be separately disposed on an inner circumferential side and an outer circumferential side of the focus ring placement surface. In this way, the focus ring attraction electrode and the focus-ring-side radio-frequency bias electrode can be comparatively easily formed.

[3] In the first wafer placement table described above, (the wafer placement table described in [1] or [2] above), the focus ring attraction electrode and the focus-ring-side radio-frequency bias electrode may be alternately disposed in plan view in the focus ring placement surface. In this way, attracting of the focus ring to the focus ring placement surface and generating of plasma above the focus ring can be well balanced.

[4] In the first wafer placement table described above, (the wafer placement table described in any one of [1] to [3] above), a wafer attraction electrode and a wafer-side radio-frequency bias electrode to which the bias radio frequency is supplied may be embedded in the plate central portion so as to be arranged in order of proximity to the wafer placement surface. In this way, since the wafer attraction electrode and the wafer-side radio-frequency bias electrode are provided at different heights (different stages), each of the electrodes can be provided substantially throughout the wafer placement surface in plan view. Thus, the attractive force for the wafer can be sufficiently increased, and the plasma can be substantially uniformly generated above the wafer.

[5] In the first wafer placement table described above, (the wafer placement table described in any one of [1] to [4] above), at a same height from the wafer placement surface in the plate central portion, the wafer attraction electrode and the wafer-side radio-frequency bias electrode to which the bias radio frequency is supplied may be embedded. In this way, since the wafer attraction electrode and the wafer-side radio-frequency bias electrode are provided at the same height (same stage), the distance from the wafer attraction electrode and the wafer-side radio-frequency bias electrode to the wafer placement surface can be reduced. Thus, efficiency of generation of plasma above the wafer can be increased without obstructing attraction of the wafer (a target).

[6] In the first wafer placement table described above, (the wafer placement table described in [5] above), a ratio of an area of the wafer-side radio-frequency bias electrode to an area of the wafer attraction electrode may be greater than or equal to 0.8 and smaller than or equal to 1.2. In this way, attracting of the wafer to the wafer placement surface and generating of plasma above the wafer can be well balanced.

[7] In the first wafer placement table described above, (the wafer placement table described in [5] or [6] above), the wafer attraction electrode and the wafer-side radio-frequency bias electrode may be alternately disposed in plan view in the wafer placement surface. Also in this way, attracting of the wafer to the wafer placement surface and generating of plasma above the wafer can be well balanced.

[8] A second wafer placement table according to the present invention includes a ceramic plate that includes a wafer placement surface having a circular shape, and a conductive substrate that is provided on a lower surface of the ceramic plate and that is used as a radio-frequency source electrode. At a same height from the wafer placement surface in the ceramic plate, a wafer attraction electrode and a wafer-side radio-frequency bias electrode to which a bias radio frequency is supplied are embedded.

In this wafer placement table, the wafer-side radio-frequency bias electrode is disposed at the same height as the wafer attraction electrode instead of being disposed below the wafer attraction electrode. Thus, the distance between the wafer-side radio-frequency bias electrode and the wafer placement surface (corresponding to the above-described thickness of the dielectric layer) reduces, and the capacitance between them increases. Accordingly, efficiency of generation of plasma above the wafer increases. Since the distance between the wafer attraction electrode and the wafer placement surface is small, no inconvenience is caused for the attraction of the wafer to the wafer placement surface. Thus, efficiency of generation of plasma above the wafer can be increased without obstructing attraction of the wafer (a target).

[9] In the second wafer placement table described above, (the wafer placement table described in [8] above), a ratio of an area of the wafer-side radio-frequency bias electrode to an area of the wafer attraction electrode may be greater than or equal to 0.8 and smaller than or equal to 1.2. In this way, attracting of the wafer to the wafer placement surface and generating of plasma above the wafer can be well balanced.

[10] In the second wafer placement table described above, (the wafer placement table described in [8] or [9] above), the wafer attraction electrode and the wafer-side radio-frequency bias electrode may be alternately disposed in plan view in the ceramic plate. In this way, attracting of the wafer to the wafer placement surface and generating of plasma above the wafer can be well balanced.

### BRIEF DESCRIPTION OF THE DRAWINGS

FIG. 1 is a vertical cross-sectional view of a wafer placement table 10.

FIG. 2 is a sectional view taken along line A-A illustrated in FIG. 1.

FIG. 3 is a sectional view taken along line B-B illustrated in FIG. 1.

FIG. 4 is a vertical cross-sectional view of a wafer placement table 110.

FIG. 5 is an explanatory view illustrating disposition of an electrode 222 and an electrode 223 (horizontal cross-sectional view).

FIG. 6 is an explanatory view illustrating disposition of an electrode 322 and an electrode 323 (horizontal cross-sectional view).

FIG. 7 is an explanatory view illustrating disposition of an electrode 226 and an electrode 27 (horizontal cross-sectional view).

FIG. 8 is an explanatory view illustrating disposition of parts of electrodes 26, 26′ and part of an electrode 27 (enlarged horizontal cross-sectional view).

FIG. 9 is an explanatory view illustrating disposition of parts of the electrodes 26, 26′ and parts of the electrodes 27, 27′ (enlarged horizontal cross-sectional view).

FIG. 10 is an explanatory view illustrating disposition of part of the electrode 26 including inner teeth 26a and part of the electrode 27 including outer teeth 27a (enlarged horizontal cross-sectional view).

### DETAILED DESCRIPTION OF THE INVENTION

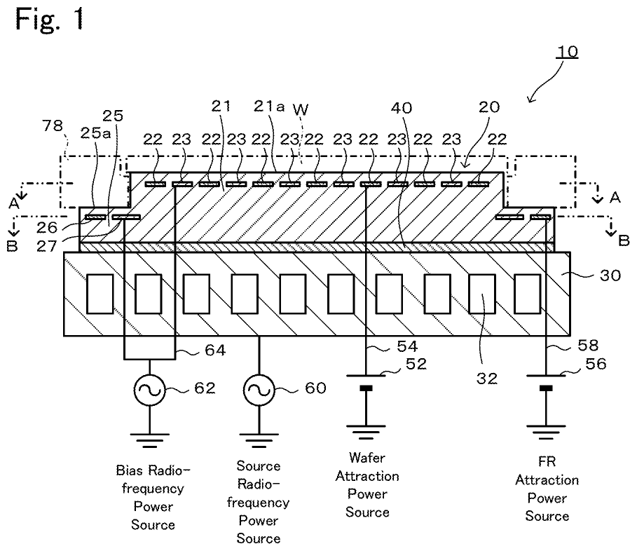

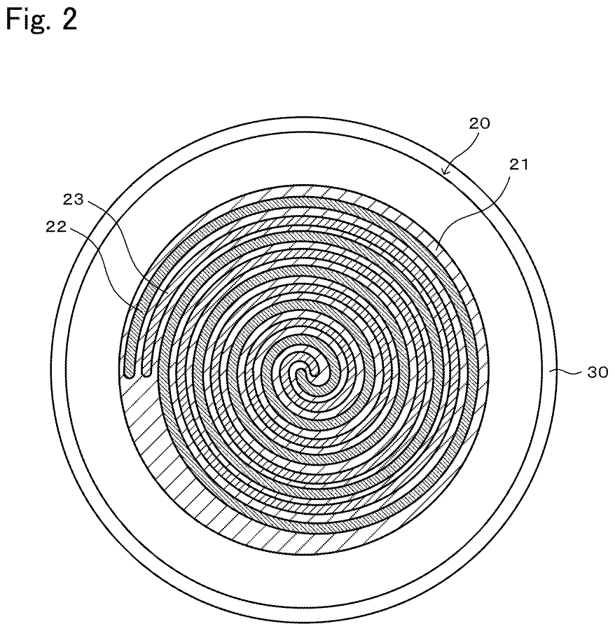

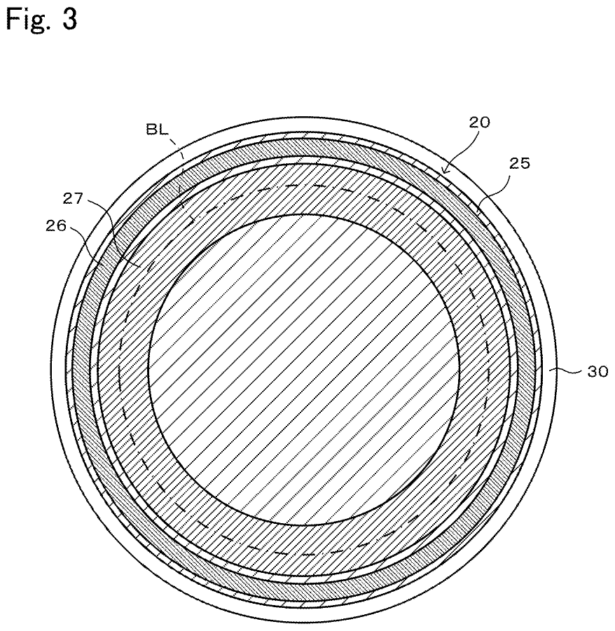

A preferred embodiment of the present invention is described below with reference to the drawings. FIG. 1 is a vertical cross-sectional view of a wafer placement table 10 (a sectional view taken along a plane including the central axis of the wafer placement table 10), FIG. 2 is a sectional view taken along line A-A illustrated in FIG. 1, and FIG. 3 is a sectional view taken along line B-B illustrated in FIG. 1.

The wafer placement table 10 is used to perform CVD, etching, or the like on a wafer W by utilizing plasma and secured in a chamber (not illustrated) for semiconductor processing for use. The wafer placement table 10 includes a ceramic plate 20, a conductive substrate 30, and a metal joining layer 40.

The ceramic plate 20 has a circular overall shape and includes a plate annular portion 25 outside a plate central portion 21 having a circular wafer placement surface 21a. The plate annular portion 25 has an annular focus ring placement surface 25a. Hereinafter, a focus ring may be abbreviated as “FR” in some cases. The wafer W is to be placed on the wafer placement surface 21a. A focus ring 78 is to be placed on the FR placement surface 25a. The ceramic plate 20 is formed of a ceramic material typical examples of which include alumina, aluminum nitride, and so forth. The FR placement surface 25a is lower than the wafer placement surface 21a by one step. An outer diameter of the ceramic plate 20, which is not particularly limited, is, for example, greater than or equal to 250 mm and smaller than or equal to 350 mm.

At the same height from the wafer placement surface 21a in the plate central portion 21, a wafer attraction electrode 22 and a wafer-side radio-frequency bias electrode 23 are embedded. These electrodes 22 and 23 are formed of a material that contains, for example, W, Mo, Ru, WC, MoC, or the like. The electrode 22 or 23 is not particularly limited in shape and may have, for example, a mesh shape or a ribbon shape.

The wafer attraction electrode 22 is a monopolar-type electrostatic electrode and, as illustrated in FIG. 2, has a spiral shape in plan view. A layer in the plate central portion 21 on the upper side of the wafer attraction electrode 22 functions as a dielectric layer. The thickness of the plate central portion 21 from an upper surface of the wafer attraction electrode 22 to the wafer placement surface 21a is preferably smaller than or equal to 1 mm. A wafer attraction power source 52 is connected to the wafer attraction electrode 22 via a power supply member 54. The power supply member 54 is electrically insulated from the metal joining layer 40 and the conductive substrate 30.

The wafer-side radio-frequency bias electrode 23 is an electrode to which a bias radio frequency is supplied and, as illustrated in FIG. 2, has a spiral shape in plan view. The bias radio frequency is lower than a source radio frequency to be supplied to the conductive substrate 30 used as a radio-frequency source electrode. For example, the bias radio frequency is hundreds of kHz and the source radio frequency is tens to hundreds of MHz. When seen in a diametral direction in plan view, the wafer attraction electrode 22 and the wafer-side radio-frequency bias electrode 23 are alternately disposed at intervals. The ratio of the area of the wafer-side radio-frequency bias electrode 23 to the area of the wafer attraction electrode 22 in the plate central portion 21 is preferably greater than or equal to 0.8 and smaller than or equal to 1.2. A bias radio-frequency power source 62 is connected to the wafer-side radio-frequency bias electrode 23 via a power supply member 64. The power supply member 64 is electrically insulated from the metal joining layer 40 and the conductive substrate 30.

At the same height from the FR placement surface 25a in the plate annular portion 25, an FR attraction electrode 26 and an FR-side radio-frequency bias electrode 27 are embedded. These electrodes 26 and 27 are formed of a material that contains, for example, W, Mo, Ru, WC, MoC, or the like. The electrode 26 or 27 is not particularly limited in shape and may have, for example, a mesh shape or a ribbon shape.

The FR attraction electrode 26 is a monopolar-type electrostatic electrode. As illustrated in FIG. 3, in plan view, the FR attraction electrode 26 has a circular annular shape and is formed on an outer circumferential side of the plate annular portion 25. A boundary line BL of FIG. 3 illustrates a boundary between the plate central portion 21 and the plate annular portion 25 for convenience. The thickness of the ceramic plate 20 from an upper surface of the FR attraction electrode 26 to the FR placement surface 25a is preferably smaller than or equal to 1 mm. An FR attraction power source 56 is connected to the FR attraction electrode 26 via a power supply member 58. The power supply member 58 is electrically insulated from the metal joining layer 40 and the conductive substrate 30.

The FR-side radio-frequency bias electrode 27 is an electrode to which a bias radio frequency is supplied. As illustrated in FIG. 3, in plan view, the FR-side radio-frequency bias electrode 27 has an annular shape and is formed on an inner circumferential side of the plate annular portion 25. The FR attraction electrode 26 and the FR-side radio-frequency bias electrode 27 are embedded so as to be, in plan view, spaced from each other with an annular gap formed therebetween. The bias radio-frequency power source 62 is connected to the FR-side radio-frequency bias electrode 27 via the power supply member 64. The power supply member 64 is electrically insulated from the metal joining layer 40 and the conductive substrate 30.

The conductive substrate 30 has a circular overall shape and is joined to a lower surface of the ceramic plate 20 with the metal joining layer 40 interposed therebetween. The conductive substrate 30 has a refrigerant flow path 32 therein that allows a refrigerant to circulate therethrough. The refrigerant flow path 32 is formed in a one-stroke pattern from one end to the other end thereof so as to distribute the refrigerant throughout the ceramic plate 20 in plan view. The one end and the other end of the refrigerant flow path 32 are connected to a refrigerant circulator (not illustrated). The refrigerant circulator is a circulating pump that has a temperature adjusting function. The refrigerant the temperature of which is adjusted to a desired temperature is introduced to the one end of the refrigerant flow path 32. The refrigerant discharged from the other end of the refrigerant flow path 32 is to be introduced again to the one end of the refrigerant flow path 32 after the temperature of the refrigerant has been adjusted to the desired temperature. The refrigerant flowing through the refrigerant flow path 32 is preferably a liquid and preferably has an electrical insulation property. Examples of a liquid having an electrical insulation property include, for example, a fluorinated inert liquid and the like. The conductive substrate 30 is fabricated from a conductive material containing metal. Examples of the conductive material include, for example, a composite material, metal, or the like. Examples of the composite material include a composite material formed of metal and ceramic and the like. Examples of the composite material formed of metal and ceramic include a metal matrix composite (MMC), a ceramic matrix composite (CMC), and the like. Specific examples of such a composite material include, for example, a material containing Si, SiC, and Ti, a material formed by impregnating a SiC porous material with Al, Si, or Al and Si. The material containing Si, SiC and Ti is referred to as SiSiCTi, the material formed by impregnating the SiC porous material with Al is referred to as AlSiC, and the material formed by impregnating the SiC porous material with Si is referred to as SiSiC. Examples of the metal include Mo. Preferably, a material having a thermal expansion coefficient close to that of the material of the ceramic plate 20 is selected as the material of the conductive substrate 30. The conductive substrate 30 is connected to a source radio-frequency power source 60 provided for generating plasma.

The metal joining layer 40 connects the lower surface of the ceramic plate 20 and an upper surface of the conductive substrate 30 to each other. The metal joining layer 40 may be a layer formed of, for example, solder or a brazing alloy. The metal joining layer 40 is formed by, for example, thermal compression bonding (TCB). The TCB refers to a known method in which a metal joining body is interposed between two members to be joined to each other, and pressure is applied to the two members to join the two members to each other in a state in which the metal joining body is heated to a temperature lower than or equal to the solidus temperature of the metal joining body.

Although it is not illustrated, the wafer placement surface 21a includes an annular seal band that is provided along an outer circumferential edge and a multiplicity of small projections that are provided on a surface inside the seal band and that have flat cylindrical shape. A top surface of the seal band and top surfaces of the small projections are at the same height (for example, a few to tens of μm), and the wafer W is supported in a state in which the wafer W is in contact with these top surfaces. The wafer placement table 10 includes a gas passage (not illustrated) for supplying a backside gas (thermally conductive gas such as an He gas) to a lower surface of the wafer W. The gas passage is provided so as to extend through the conductive substrate 30, the metal joining layer 40, and the plate central portion 21 of the ceramic plate 20 in the up-down direction.

Next, an example of use of the wafer placement table 10 is described with reference to FIG. 1. The wafer placement table 10 is secured in the chamber (not illustrated) for a semiconductor process. A shower head that releases a process gas into the chamber through a multiplicity of gas injection holes is disposed at a ceiling surface of the chamber.

The focus ring 78 is to be placed on the FR placement surface 25a of the wafer placement table 10. The wafer W is to be placed on the wafer placement surface 21a of the wafer placement table 10. The focus ring 78 has a step along an inner circumference of an upper end portion so as not to interfere with the wafer W. In this state, a direct-current voltage of the wafer attraction power source 52 is applied to the wafer attraction electrode 22 to cause the wafer W to be attracted to the wafer placement surface 21a. In addition, a direct-current voltage of the FR attraction power source 56 is applied to the FR attraction electrode 26 to cause the focus ring 78 to be attracted to the FR placement surface 25a. The inside of the chamber is set to a predetermined vacuum atmosphere (or a predetermined decompressed atmosphere), and a source radio frequency voltage is applied to the conductive substrate 30 from the source radio-frequency power source 60 while the process gas is supplied from the shower head. In addition, the bias radio frequency voltage is applied to the wafer-side radio-frequency bias electrode 23 and the FR-side radio-frequency bias electrode 27 from the bias radio-frequency power source 62. Consequently, plasma is generated between the shower head and the conductive substrate 30 (the metal joining layer 40 at the same potential as that of the conductive substrate 30) to which the source radio-frequency voltage is applied. By utilizing the plasma, a CVD and etching are performed on the wafer W. The source radio-frequency voltage is applied for producing the plasma, and the bias radio frequency voltage is applied for pulling ions into the wafer W and the focus ring 78.

When the distance between the wafer-side radio-frequency bias electrode 23 and the wafer placement surface 21a is great (that is, the thickness of a dielectric layer is great), a capacitance C between them reduces.

To address this, according to the present embodiment, the wafer-side radio-frequency bias electrode 23 is disposed at the same height as the wafer attraction electrode 22 instead of being disposed below the wafer attraction electrode 22. Thus, the distance between the wafer-side radio-frequency bias electrode 23 and the wafer placement surface 21a reduces, and the capacitance C between them increases. Accordingly, efficiency of generation of plasma increases above the wafer W. Since the distance between the wafer attraction electrode 22 and the wafer placement surface 21a is small, no inconvenience is caused for the attraction of the wafer W to the wafer placement surface 21a.

In addition, the FR-side radio-frequency bias electrode 27 is disposed at the same height as the FR attraction electrode 26 instead of being disposed below the FR attraction electrode 26. Thus, the distance between the FR-side radio-frequency bias electrode 27 and the FR placement surface 25a reduces, and the capacitance C between them increases. Accordingly, efficiency of generation of plasma above the focus ring 78 increases. Since the distance between the FR attraction electrode 26 and the FR placement surface 25a is small, no inconvenience is caused for the attraction of the focus ring 78 to the FR placement surface 25a.

As a plasma process is being performed on the wafer W, the focus ring 78 is worn. However, since the focus ring 78 is thicker than the wafer W, replacement of the focus ring 78 is to be performed after a plurality of wafers W have been processed.

With the above-described wafer placement table 10, the efficiency of generation of plasma above the wafer W can be increased without obstructing attraction of the wafer W, and the efficiency of generation of plasma above the focus ring 78 can be increased without obstructing attraction of the focus ring 78.

Furthermore, the ratio of the area of the wafer-side radio-frequency bias electrode 23 to the area of the wafer attraction electrode 22 is preferably greater than or equal to 0.8 and smaller than or equal to 1.2. In this way, attracting of the wafer W to the wafer placement surface 21a and generating of plasma above the wafer W can be well balanced.

Furthermore, in the plate central portion 21, the wafer attraction electrode 22 and the wafer-side radio-frequency bias electrode 23 are alternately disposed in plan view. Thus, attracting of the wafer W to the wafer placement surface 21a and generating of plasma above the wafer W can be better balanced.

Furthermore, in plan view, the FR attraction electrode 26 and the FR-side radio-frequency bias electrode 27 are separately disposed on the inner circumferential side and the outer circumferential side of the FR placement surface 25a. Thus, the FR attraction electrode 26 and the FR-side radio-frequency bias electrode 27 can be comparatively easily formed.

Of course, the present invention is in no way limited to the above-described embodiment and can be carried out in a variety of forms without departing from the technical scope of the present invention.

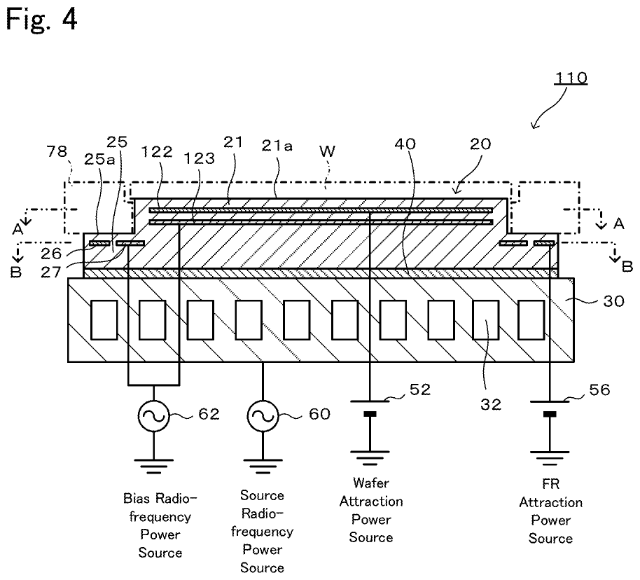

At the same height in the plate central portion 21, the wafer attraction electrode 22 and the wafer-side radio-frequency bias electrode 23 are embedded according to the above-described embodiment. However, it is not limiting. For example, as in a wafer placement table 110 illustrated in FIG. 4, a wafer attraction electrode 122 and a wafer-side radio-frequency bias electrode 123 are embedded in the plate central portion 21 so as to be arranged in order of proximity to the wafer placement surface 21a. In FIG. 4, the same elements as those in the above-described embodiment are denoted by the same reference numerals. The shape of the electrode 122 or 123 is not particularly limited. The shape of the electrodes 122 and 123 may be, for example, a circular plate shape or a circular mesh shape. Both the electrodes 122 and 123 are embedded substantially parallel to the wafer placement surface 21a. Since the wafer attraction electrode 122 and the wafer-side radio-frequency bias electrode 123 are provided at different heights (different stages) in the wafer placement table 110, each of the electrodes 122 and 123 can be provided substantially throughout the wafer placement surface 21a in plan view. Thus, the attractive force for the wafer W can be sufficiently increased, and the plasma can be substantially uniformly generated above the wafer W.

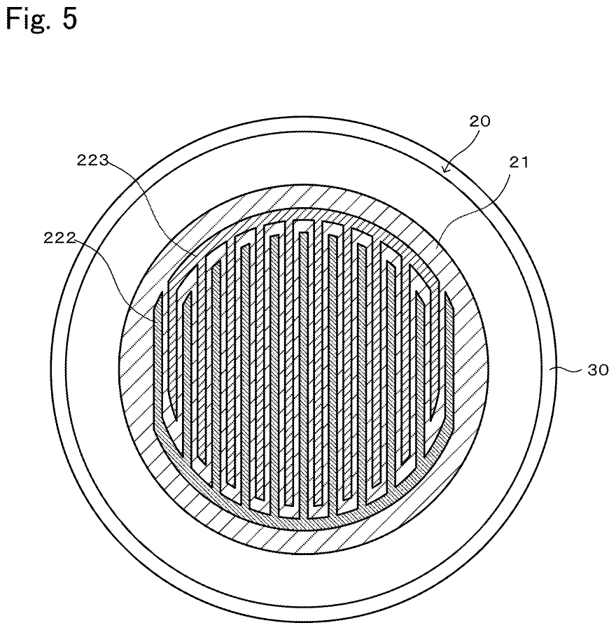

At the same height in the plate central portion 21 of the ceramic plate 20, the wafer attraction electrode 22 and the wafer-side radio-frequency bias electrode 23 each of which has a spiral shape are alternately disposed in plan view according to the above-described embodiment. However, it is not limiting. For example, as illustrated in FIG. 5, at the same height in the plate central portion 21 of the ceramic plate 20, a wafer attraction electrode 222 and a wafer-side radio-frequency bias electrode 223 each of which has a comb shape may be alternately disposed when seen in the diametral direction in plan view (that is, one of teeth of one of the electrodes 222 and 223 is disposed between two of teeth of the other of the electrodes 222 and 223).

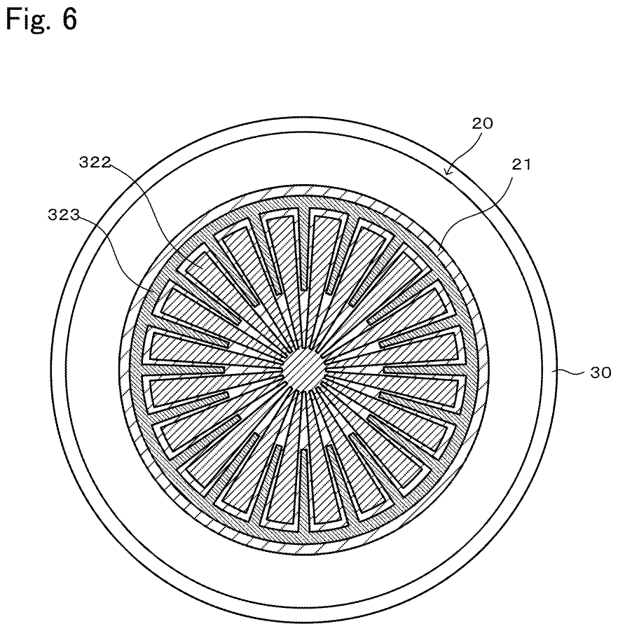

Alternatively, as illustrated in FIG. 6, at the same height in the plate central portion 21 of the ceramic plate 20, a wafer attraction electrode 322 having a shape in which a plurality of outer teeth radially extend from a circular plate at the center and a wafer-side radio-frequency bias electrode 323 having a shape in which inner teeth extend from a circular ring along the outer circumference to spaces between the outer teeth of the wafer attraction electrode 322 may be alternately disposed in plan view when seen in a circumferential direction.

According to the above-described embodiment, at the same height in the plate annular portion 25 of the ceramic plate 20, the FR attraction electrode 26 having an annular shape and the FR-side radio-frequency bias electrode 27 having an annular shape are respectively disposed on the outer circumferential side and the inner circumferential side in plan view. However, it is not limiting. For example, the FR attraction electrode 26 and the FR-side radio-frequency bias electrode 27 may be respectively disposed on the inner circumferential side and the outer circumferential side.

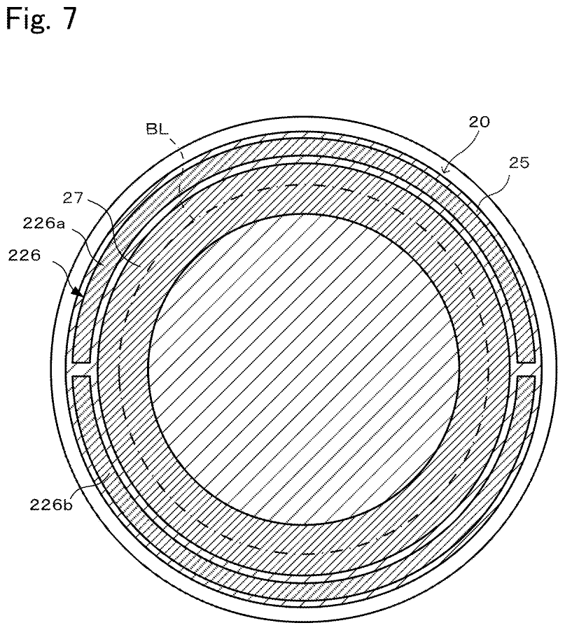

Alternatively, as illustrated in FIG. 7, a bipolar-type FR attraction electrode 226 may be disposed instead of the monopolar-type FR attraction electrode 26. In FIG. 7, the same elements as those in the above-described embodiment are denoted by the same reference numerals. The FR attraction electrode 226 includes a pair of semi-circular electrodes 226a and 226b disposed so as to face each other with a gap formed therebetween.

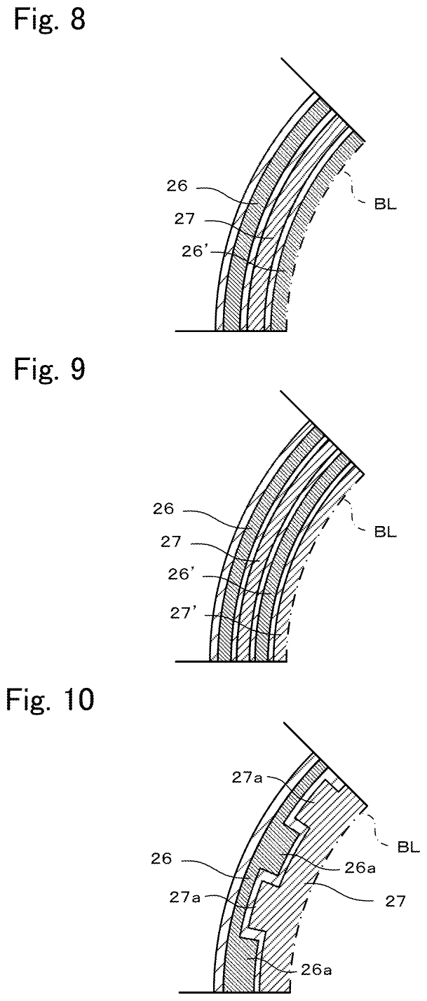

As illustrated in FIG. 8, according to the above-described embodiment, the annular FR attraction electrode 26, the annular FR-side radio-frequency bias electrode 27, and an annular FR attraction electrode 26′ which are concentric with each other may be alternately disposed in the radial direction. Alternatively, as illustrated in FIG. 9, the annular FR attraction electrode 26, the annular FR-side radio-frequency bias electrode 27, the annular FR attraction electrode 26′, and an annular FR-side radio-frequency bias electrode 27′ which are concentric with each other may be alternately disposed in the radial direction. Referring to FIGS. 8 and 9, when seen in the radial direction in plan view, the FR attraction electrode and the FR-side radio-frequency bias electrode are alternately disposed. In this way, attracting of the focus ring 78 to the FR placement surface 25a and generating of plasma above the focus ring 78 can be better balanced.

According to the above-described embodiment, as illustrated in FIG. 10, the annular FR attraction electrode 26 may have a plurality of inner teeth 26a, the annular FR-side radio-frequency bias electrode 27 may have a plurality of outer teeth 27a, outer teeth 27a may be disposed between the inner teeth 26a with a gap formed therebetween, and the inner teeth 26a may be disposed between the outer teeth 27a with the gap formed therebetween. Referring to FIG. 10, when seen in the circumferential direction in plan view, the FR attraction electrode 26 and the FR-side radio-frequency bias electrode 27 alternate. Also in this way, attracting of the focus ring 78 to the FR placement surface 25a and generating of plasma above the focus ring 78 can be better balanced.

Although the wafer attraction power source 52 and the FR attraction power source 56 are separately provided according to the above-described embodiment, a single direct-current power source may be used as a common power source for both wafer attraction and FR attraction.

Although the bias radio-frequency power source 62 is used as a common power source for both the wafer side and the FR side according to the above-described embodiment, a wafer-side bias radio-frequency power source and an FR side bias radio-frequency power source may be separately prepared.

Although the ceramic plate 20 and the conductive substrate 30 are joined with the metal joining layer 40 according to the above-described embodiment, it is not limiting. For example, a resin joining layer may be used instead of the metal joining layer 40.

In the above-described embodiment, a heater electrode (resistance heating element) may be provided in the plate central portion 21 and a heater electrode (resistance heating element) may be provided in the plate annular portion 25.

Although the ceramic plate 20 in which the plate central portion 21 and the plate annular portion 25 are integrated with each other is employed according to the above-described embodiment, the plate central portion 21 and the plate annular portion 25 may be separately provided.

The present application claims priority from Japanese Patent Application No. 2022-059152, filed on Mar. 31, 2022, the entire contents of which are incorporated herein by reference.

What is claimed is:

1. A wafer placement table comprising:
a ceramic plate including a plate annular portion that includes a focus ring placement surface which has an annular shape and which is disposed outside a plate central portion including a wafer placement surface having a circular shape; and
a conductive substrate that is provided on a lower surface of the ceramic plate and that is used as a radio-frequency source electrode, wherein
at a same height from the focus ring placement surface in the plate annular portion, a focus ring attraction electrode and a focus-ring-side radio-frequency bias electrode to which a bias radio frequency is supplied are embedded.

2. The wafer placement table according to claim 1, wherein,
in plan view, the focus ring attraction electrode and the focus-ring-side radio-frequency bias electrode are separately disposed on an inner circumferential side and an outer circumferential side of the focus ring placement surface.

3. The wafer placement table according to claim 1, wherein
the focus ring attraction electrode and the focus-ring-side radio-frequency bias electrode are alternately disposed in plan view in the focus ring placement surface.

4. The wafer placement table according to claim 1, wherein
a wafer attraction electrode and a wafer-side radio-frequency bias electrode to which the bias radio frequency is supplied are embedded in the plate central portion so as to be arranged in order of proximity to the wafer placement surface.

5. The wafer placement table according to claim 1, wherein
at a same height from the wafer placement surface in the plate central portion, a wafer attraction electrode and a wafer-side radio-frequency bias electrode to which the bias radio frequency is supplied are embedded.

6. The wafer placement table according to claim 5, wherein
a ratio of an area of the wafer-side radio-frequency bias electrode to an area of the wafer attraction electrode is greater than or equal to 0.8 and smaller than or equal to 1.2.

7. The wafer placement table according to claim 5, wherein,
the wafer attraction electrode and the wafer-side radio-frequency bias electrode are alternately disposed in plan view in the wafer placement surface.

8. A wafer placement table comprising:
a ceramic plate that includes a wafer placement surface having a circular shape; and
a conductive substrate that is provided on a lower surface of the ceramic plate and that is used as a radio-frequency source electrode, wherein
at a same height from the wafer placement surface in the ceramic plate, a wafer attraction electrode and a wafer-side radio-frequency bias electrode to which a bias radio frequency is supplied are embedded.

9. The wafer placement table according to claim 8, wherein
a ratio of an area of the wafer-side radio-frequency bias electrode to an area of the wafer attraction electrode is greater than or equal to 0.8 and smaller than or equal to 1.2.

10. The wafer placement table according to claim 8, wherein,
the wafer attraction electrode and the wafer-side radio-frequency bias electrode are alternately disposed in plan view in the ceramic plate.
